(19) United States
(12) Patent Application Publication
(10) Pub. No.: US 2011/0250039 A1
(43) Pub. Date: Oct. 13, 2011

(54) MODULAR CARRIER

(75) Inventors: Joerg Petzold, Dessau (DE); Frank Wegert, Holzweissig (DE)

(73) Assignee: Q-CELLS SE, BITTERFELD-WOLFEN (DE)

(21) Appl. No.: 13/140,096

(22) PCT Filed: Dec. 14, 2009
(86) PCT No.: PCT/DE2009/001767

§ 371 Date: Jun. 16, 2011

(30) Foreign Application Priority Data
Dec. 16, 2008 (DE) 10 2008 062 123.4

(51) Int. Cl. H01L 21/673

(52) U.S. Cl. 414/222.01

(57) ABSTRACT

The invention relates to a modular carrier for receiving, storing and transporting thin planar workpieces/semi-finished products, such as wafers for photovoltaic elements, in vertical positions that are parallel to each other and uniformly spaced. This problem is solved by a modular design of the carrier. The required components are combined into three modules. The first module is the groove plate having the horizontal support arranged beneath in an angled shape. The second module is formed by the two U-shaped end plates. The third module comprises the spacer rods, which are arranged between said two U-shaped end plates and of which two in each case receive a groove plate at the top and the bottom. The groove plates and the spacer rods are used at the length L, wherein the length L is uniformly graduated. In this way, the carrier can be produced in the length L or n×L, with n always being an integer. Two groove plates are always arranged parallel to each other, with opposing grooves being located on a straight line. The distance of said grooves among each other is so large that a thin planar workpiece/semi-finished product can be easily inserted. The workpiece/semi-finished product rests against the support surface.

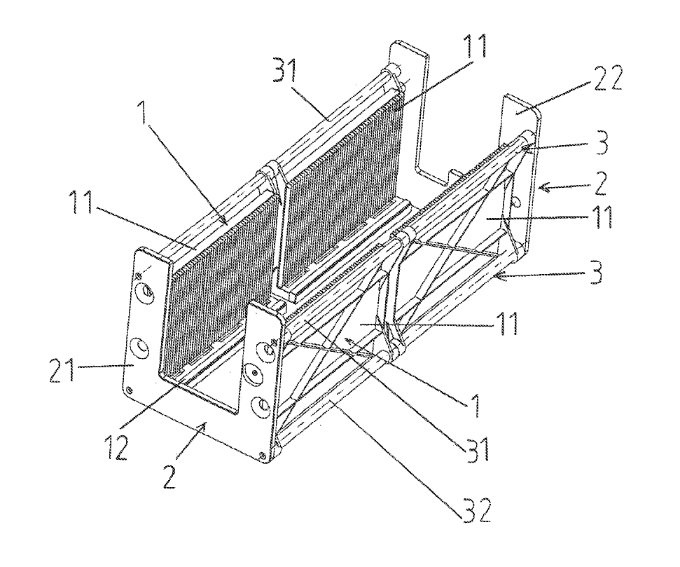

The invention relates to a modular carrier for receiving, for storing and for transporting thin, flat workpieces/semi-finished products, for example wafers for photovoltaics, in a position in which they are parallel to and at the same distance from one another.

In order for it to be possible for wafers for photovoltaic elements to be processed in an automatic process, they are received by a carrier in a position in which they are parallel to and at the same distance from one another. By way of example, document DE 20 2007 003 416 U1 discloses a carrier of this kind which comprises two walls which are opposite one another, a plurality of connecting elements which connect the walls, and a holding structure for holding the wafers in the carrier. To this end, a large number of individual parts are required with the elements which are provided for this purpose.

The invention is based on the object of developing a carrier for accommodating thin, flat workpieces/semi-finished products which comprises as few individual parts as possible.

This object is achieved in accordance with the characterizing part of the main claim by modular design of the carrier.

The required components are combined to form three modules. The first module is the groove panel with the horizontal support arranged beneath it at an angle. The second module is formed by the two U-shaped end panels. The third module comprises the spacer bars which are arranged between these two U-shaped end panels, in each case two of said spacer bars receiving a groove panel at the top and at the bottom.

The groove panels and the spacer bars are used with the length L, with the length L being a uniform gradation. The carrier can thus be produced with the length L or n×L, where n is always a whole number. Two groove panels are always arranged parallel to one another, in this case the grooves are located in a straight line. The distance between these grooves is such that a thin, flat workpiece/semi-finished product can be easily inserted. The workpiece/semi-finished product is held by the support face at the bottom. Said support face is elastic, in order to cushion the workpiece/semi-finished product as it is received. In order for the workpiece/semi-finished product to not be laterally displaced in an undesired manner, the surface of the support can either be rough or be in the form of a groove.

In order to be able to firmly hold the thin, flat workpieces/semi-finished products in the grooves in the groove panels and possibly in the supports, the receiving faces of the grooves are elastic. The material of the workpieces/semi-finished products is protected by virtue of the damping effect created by said elasticity. As an alternative, the receiving faces of the grooves can be formed with varying frictional value. This has the effect of inhibiting displacement in the event of external influences.

Further details and advantages of the subject matter of the invention can be found in the following description and the associated drawing which shows a perspective illustration of a modular carrier.

The modular carrier comprises three modules: groove panel 1, end panels 2 and spacer bars 3. The groove panel 1 module contains the groove panels 11 with the supports 12, said groove panels being situated opposite one another. This groove panel 1 module has the length L. In this case, the groove panels 11 are arranged in a manner situated opposite one another such that a groove is always located on a common line. Each of the two groove panels 11 is held by in each case a spacer bar 31, 32 at the top and at the bottom. To this end, the groove panel 11 is provided with corresponding holes. Each of the two spacer bars 31, 32 is screwed to an end panel 21 and 22 on either side. The distance between two groove panels 11 which are situated opposite one another is such that the material which comprises thin, flat workpieces/semi-finished products, for example wafers for photovoltaic elements, can be received.

In the carrier according to the exemplary embodiment, in each case two groove panels 11 with the individual length L are arranged one behind the other. In this case, the length of each of the spacer bars 31, 32 is 2L. However, as an alternative, it is also possible for in each case 2 individual spacer bars with the individual length L to be screwed to one another, 31 to 31 and 32 to 32, and therefore to obtain the length 2L. A corresponding method is followed given longer design of the carrier.

The faces of the lower supports 12 are elastic, and therefore the flat material is cushioned at the bottom as it is received. Since ever thinner material is being used to an increasing extent, there is also a risk of said material sagging at the sides. In order to prevent this, the surface is either self-impeding by being roughened or is provided with grooves like the groove panels 11.

In order to adequately hold and protect the material, which is in the form of thin, flat workpieces/semi-finished products, in the grooves in the groove panels 11 and possibly the supports 12, said grooves can be elastic and/or of friction-reducing design at their receiving faces.

In order to achieve an anti-static effect which additionally protects the workpieces/semi-finished products, the groove panels 11 and possibly grooves which are located in the supports 12 can be anti-static at their receiving faces. This structural design of the carrier in a modular manner is associated with the advantage that fewer individual parts are required, together with a simple design.

1-9. (canceled)

10. A modular carrier for receiving, for storing and for transporting flat material of the same size, comprising two U-shaped end panels which are arranged on either side, two groove panels which are opposite to and at a distance from one another, lower stops and spacer bars which connect the two U-shaped end panels to one another without twisting, with the grooves in the groove panels being arranged in relation to one another such that they are located opposite each other in each case in a straight line and the distance between them is equal to the width of a flat material plus a difference measure, characterized in that the individual components comprise three modules, with the first module being the groove panel with the horizontal support arranged beneath it at an angle, and the groove panel and the support having a common length L, the two U-shaped end panels forming the second module, and the third module, as the upper and lower spacer bars with the length L, firmly holding a respective groove panel and connecting the two U-shaped end panels to one another in a torsionally rigid manner.

11. The modular carrier as claimed in claim 10, characterized in that it has a length L or n×L plus the thickness of the two end panels, where n is always a whole number.

12. . The modular carrier as claimed in claim 10, characterized in that the horizontal support of the first module has an elastic surface which is either rough or, like the groove panels, is provided with grooves.

13. The modular carrier as claimed in claim 10, characterized in that the groove panels are provided with holes through which spacer bars are inserted.

14. The modular carrier as claimed in claim 13, characterized in that connections which can operate without tools are provided as an alternative for the purpose of connecting the groove panels to the spacer bars in an interlocking manner.

15. The modular carrier as claimed in claim 13, characterized in that the spacer bars are used as one piece either with the length L or n×L, or are composed of a plurality of pieces with the length n×L.

16. The modular carrier as claimed in claim 10, characterized in that the grooves which are located in the groove panels and possibly in the supports are elastic at their receiving faces.

17. The modular carrier as claimed in claim 10, characterized in that the groove panels (11) and possibly grooves which are located in the supports have a higher frictional value at their receiving faces.

18. The modular carrier as claimed in claim 10, characterized in that the groove panels are anti-static.
